(19) United States
(12) Patent Application Publication
(10) Pub. No.: US 2002/0167310 A1
(43) Pub. Date: Nov. 14, 2002

(54) Angle transmitter

(75) Inventors: Herbert Wallner, Schonaich (DE); Roberto Dupraz, Breganzona (CH)

Correspondence Address: Gudrun E. Huckett, Ph.D., P.O. Box 3187, Albuquerque, NM, 87190-3187, US

(73) Assignee: Faulhaber GmbH & Co. KG Feinmechanische Werkstatten, Schonaich (DE)

(21) Appl. No.: 10/139,415

(22) Filed: May 6, 2002

(30) Foreign Application Priority Data
May 8, 2001 (DE) 101 22 277.7

(51) Int. Cl. G01B 7/30; G01R 33/06

(52) U.S. Cl. 324/207.25; 324/207.21; 324/207.2

(57) ABSTRACT

An angular transmitter integrated with a small electrical motor and supplying phase-shifted signals has at least one magnetic part having an end face and alternatingly arranged poles on the end face. At least one sensor is arranged opposed to the at least one magnetic part. The at least one sensor has at least two sensor elements arranged angularly relative to one another. The at least two sensor elements are rotated relative to one another by 90° or by 60°. The at least two sensor elements cross one another.

### BACKGROUND OF THE INVENTION

1. Field of the Invention

The invention relates to an angle transmitter integrated with a small electrical motor and comprised of at least one magnetic part which is provided at its end face with alternatingly arranged poles and which has at least one sensor positioned opposite thereto, wherein the angle transmitter supplies phase-shifted signals.

2. Description of the Related Art

The angle transmitter has a magnetic part which is fixedly connected with the motor shaft and enables the precise governing of rotational speed and rotational direction of the motor shaft as well as a positioning of the motor. The smaller the motors in which the angle transmitter is used, the greater the problem of achieving a high precision with reasonable expenditure.

### SUMMARY OF THE INVENTION

It is an object of the present invention to configure an angle transmitter of the aforementioned kind such that it provides high resolution while being of a small size.

In accordance with the present invention, this is achieved in that the sensor has at least two sensor elements which are positioned angularly relative to one another.

In the angle transmitter according to the invention, the sensor is provided with at least two sensor elements which are arranged angularly to one another. The sensor thus supplies phase-shifted high-quality signals which result in a high angle precision. The angle transmitter according to the invention enables moreover a high resolution. The sensor elements can have very small dimensions so that the angle transmitter overall is very compact. It is suitable particularly for small or miniature motors which have an outer diameter of only approximately 4 mm to 6 mm and an axial length of, for example, only 10 mm to 20 mm.

### BRIEF DESCRIPTION OF THE DRAWING

In the drawing:

FIG. 1 is a schematic illustration of the angle transmitter according to the invention;

FIG. 2 is a view of a magnetic ring of the angle transmitter according to FIG. 1;

FIG. 3 is an illustration corresponding to FIG. 1 of a second embodiment of the angle transmitter according to the invention;

FIG. 4 is an enlarged illustration of a sensor of the angle transmitter according to the invention;

FIG. 5 shows a second embodiment of a sensor of the angle transmitter according to the invention;

FIG. 6 shows an amplitude-angle diagram for the sensor according to FIG. 4;

FIG. 7 shows the conversion of the amplitude-angle diagram according to FIG. 6 into a sine-cosine diagram;

FIG. 8 is an illustration according to FIG. 1 of a third embodiment of the angle transmitter according to the invention; and

FIG. 9 is a view of the magnetic disc of the angle transmitter according to FIG. 8.

### DESCRIPTION OF THE PREFERRED EMBODIMENTS

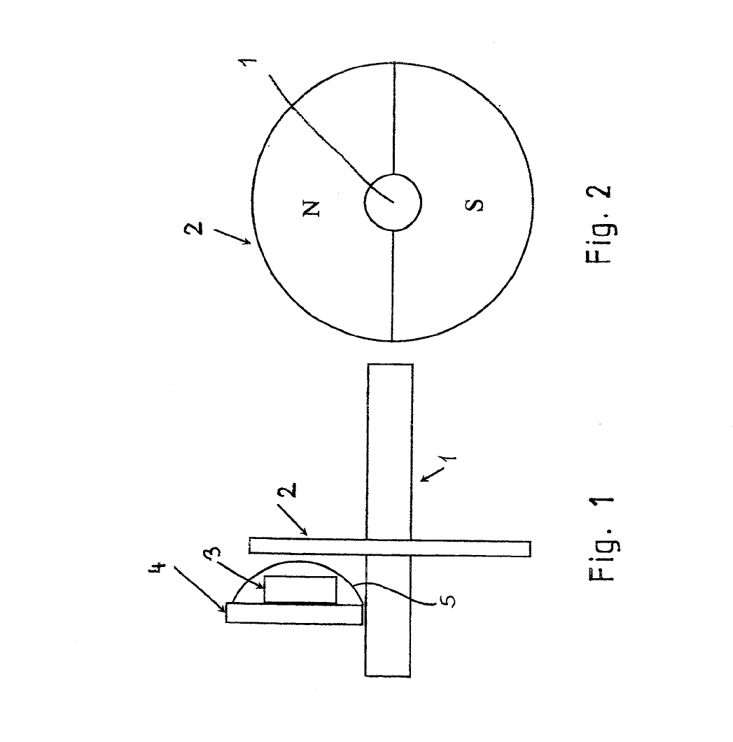

The angle transmitter is configured to be integrated with small electrical motors and serves for providing exact governing of the rotational speed and rotational direction as well as the precise positioning of the small motors. The angle transmitter according to FIGS. 1 and 2 has a magnetic ring 2 mounted on a motor shaft 1 of a small motor (not illustrated). The magnetic ring 2 has, for example, a circular contour, as illustrated in FIG. 2, and is seated fixedly on the motor shaft 1. The magnetic ring 2 is magnetized at the end face over a semi-circle as the north pole N and on the other semi-circle area as the south pole S. This can be realized, for example, by magnetization in a diametrical direction by means of a homogenous magnetic field. The magnetic ring 2 has, for example, a diameter of only 3 mm.

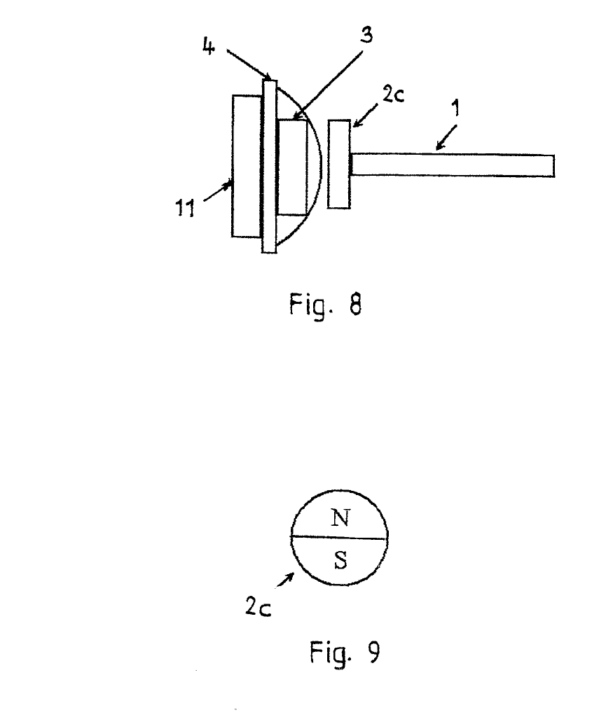

In the embodiment according to FIGS. 1 and 2, the magnetic ring 2 is positioned at a distance from the ends of the motor shaft 1. It is also possible to attach a magnetic disc 2c (FIGS. 8 and 9) on one end of the motor shaft 1. In this case, the magnetic part 2 is not penetrated by the motor shaft 1 so that it is of a disc-shaped configuration.

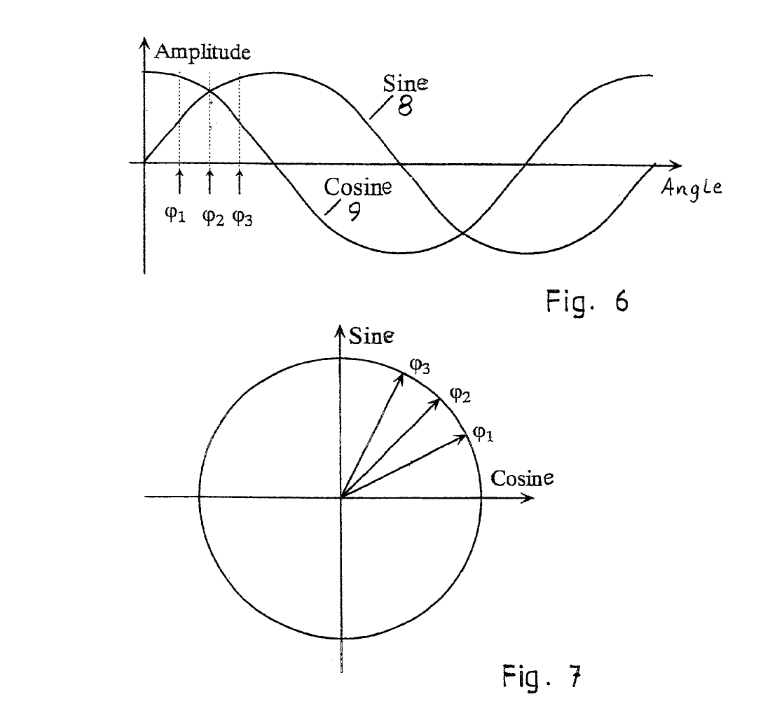

A sensor 3 is positioned opposite the magnetic ring 2; the sensor 3 is advantageously a Hall sensor or a magneto-resistive sensor. It is seated on a support 4, for example, a PCB (printed circuit board), on which may be provided optionally also an evaluation IC (integrated circuit) 11 (FIGS. 8 and 9). The latter is positioned advantageously on the side of the support 4 facing away from the sensor 3. The sensor 3 is advantageously positioned under, and thus protected by, a cover 5 which is attached to the support 4. The sensor 3 detects the magnetic field emitted by the magnetic ring 2 upon rotation of the motor shaft 1. As illustrated in FIG. 4, the sensor 3 has a horizontal sensor element 6 and a vertical sensor element 7 which are arranged so as to cross one another perpendicularly. The two sensor elements 6, 7 in the illustrated embodiment have the same rectangular contour and cross one another at half their length. As a result of the sensor elements 6, 7 being positioned perpendicularly to one another, the sensor 3 provides two sine-shaped signals 8, 9 (FIG. 6) which are phase-shifted by 90° relative to one another. Because of the phase shift by 90°, the signal 8 corresponds to a sine curve and the signal 9 to the matching cosine curve. For example, in FIG. 6, three rotational angles φ₁ to φ₃ are illustrated, and the corresponding amplitude values can be correlated therewith. As illustrated in FIG. 7, in this way the respective rotational angle of the motor shaft 1 can be determined very precisely.

The sensor elements 6, 7 which are rotated relative to one another by 90° provide high-quality sine-cosine signals which provide a high angular precision. The sine-shaped signals (quadrature signals) enable the determination of the absolute position within a complete revolution of the motor shaft 1.

When magneto-resistive sensor elements are used, the absolute position of the motor shaft 1 can be precisely determined within one half revolution of the motor shaft.

The evaluation of the quadrature signals 8, 9 is realized preferably after amplification of the sensor signals. For this purpose, an interpolator circuit can be provided which advantageously is integrated into the angle transmitter and provides two 90° phase-shifted encoder signals with a pulse number which is determined by the interpolator circuit. Since such an interpolator circuit is known in general, it will not be described in detail in this context.

As an alternative, the interpolator circuit can also provide the absolute position value, for example, by means of a serial interface.

The evaluation of the quadrature signals after amplification can also be realized by an evaluation algorithm which is provided external to the angle transmitter, for example, by means of a software program provided on a computer. In this type of evaluation, additional corrections of systematic errors are possible, for example, amplitude errors, offset errors or shape errors (deviations from the sine shape). In this way, an even greater precision can be achieved.

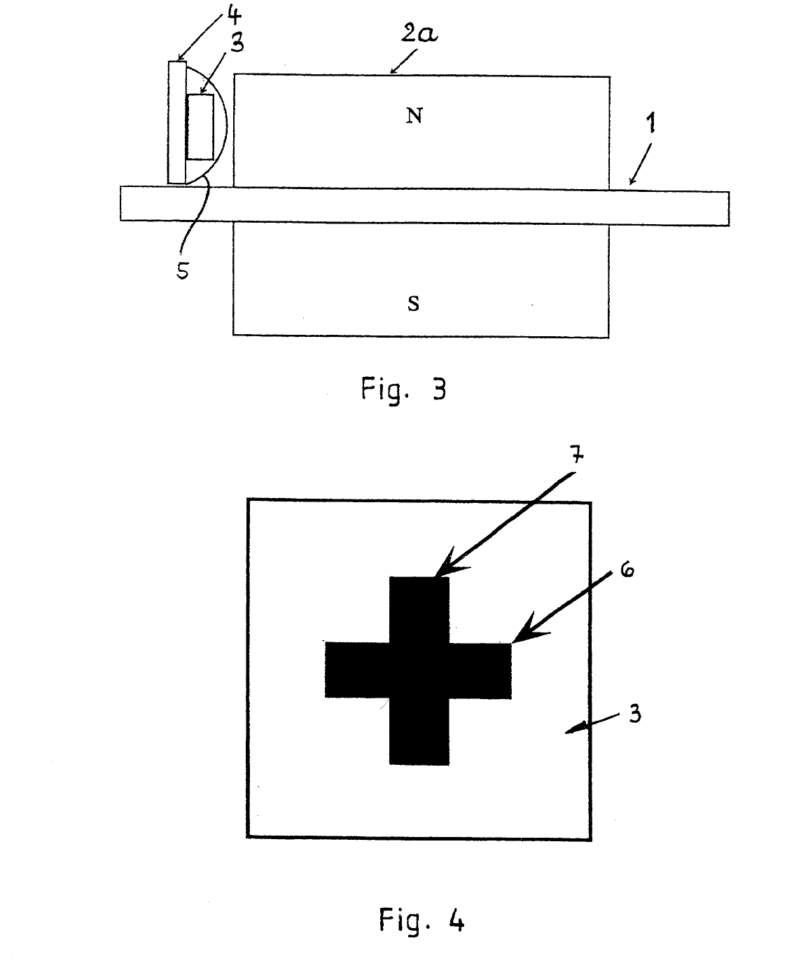

FIG. 3 shows an embodiment in which a motor magnet 2a is fixedly mounted on the motor shaft 1. The motor shaft 1 penetrates the motor magnet 2a centrally. One half is magnetized as a north pole N and the other half is magnetized as the south pole S. The sensor 3 is again positioned opposite the motor magnet 2a and is mounted on the support 4 under the cover 5. The sensor 3 can be embodied corresponding to the embodiment according to FIG. 4.

In the embodiment according to FIGS. 8 and 9, the magnetic disc 2c is positioned centrally at the end of the motor shaft 1. The magnetic disc 2c, corresponding to the embodiment of FIGS. 1 and 2, is magnetized at the end face about a semi-circle area as a north pole and on the other semi-circle area as a south pole (FIG. 9). The magnetic disc 2c is centrally arranged before the sensor 3 in the axial direction. Otherwise, this embodiment is identical to the embodiment of FIGS. 1 and 2. The center position of the magnet disc 2c results in a very compact configuration of the angle transmitter.

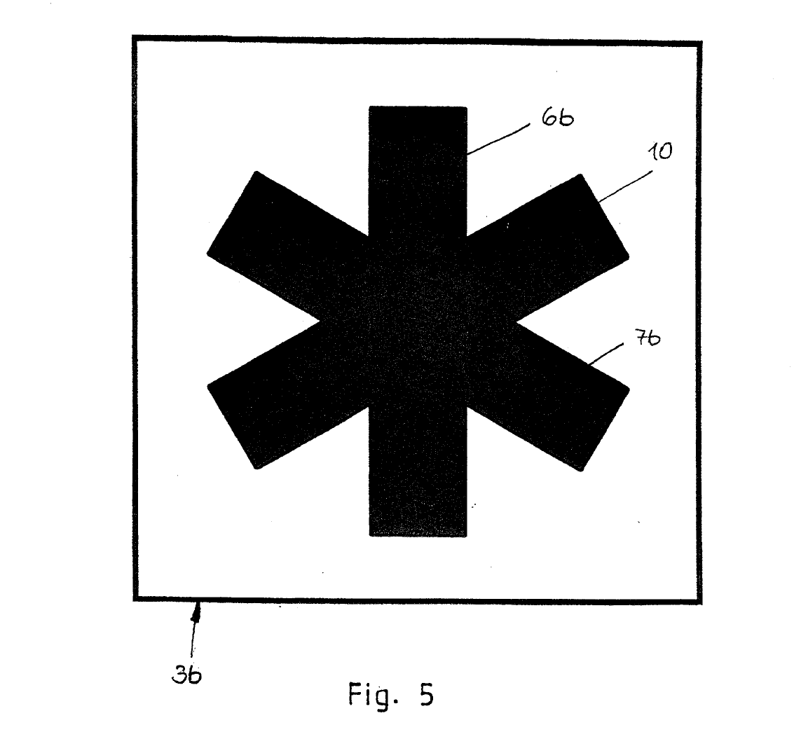

FIG. 5 shows a sensor 3b which can be used in the embodiments of FIGS. 1 and 2, 3 or 8, 9. The sensor 3b has three sensor elements 6b, 7b, 10 which are identical, respectively, and have a rectangular shape. The three sensor elements 6b, 7b, 10 are arranged at half their length in a crossing arrangement and are staggered by 60°, respectively. Accordingly, this sensor 3b provides three sine-shaped signals which are phase-shifted electrically by 120° relative to one another.

The described angle transmitter is characterized by a very compact configuration because the sensors 3, 3b have very small dimensions. Their dimension measured perpendicularly to the motor shaft 1 is, for example, only approximately 1.5 mm. The sensor 3, 3b is positioned at a small spacing opposite the magnetic ring 2 or the motor magnets 2a and has only a minimal spacing from the motor shaft 1. When the sensors 3, 3b are formed as vertical Hall sensors, as illustrated in the embodiments, the angle transmitter has a high resolution and great precision. When the sensors 3, 3b are embodied as magneto-resistive sensors, an extremely compact configuration combined with high resolution and precision is obtained also.

The angle transmitter can be integrated into a brushless or into a brush-type small direct-current motor with air-core coil. The sine-shaped signals 8, 9 are evaluated as part of the angle transmitter either within the small motor or external thereto.

The evaluation of the signals 8, 9 can be performed, instead of employing an interpolator circuit, also by means of a microprocessor, a digital logic circuit or the like.

The evaluation of the sensor signals can be realized such that the output signal provides the absolute position of the motor shaft 1 within an integral part of a revolution of the motor shaft 1. Advantageously, the output signal provides the absolute position of the motor shaft 1 within one revolution.

While specific embodiments of the invention have been shown and described in detail to illustrate the inventive principles, it will be understood that the invention may be embodied otherwise without departing from such principles.

What is claimed is:

1. An angular transmitter configured to be integrated with a small electrical motor and supplying phase-shifted signals, the angular transmitter comprising:
at least one magnetic part (2, 2a, 2b) having an end face and alternatingly arranged poles (N, S) on the end face;
at least one sensor (3, 3b) arranged opposed to the at least one magnetic part (2, 2a, 2b);
wherein the at least one sensor (3, 3b) comprises at least two sensor elements (6, 7; 6b, 7b, 10) arranged angularly relative to one another.

2. The angular transmitter according to claim 1, wherein the at least two sensor elements (6, 7) are rotated relative to one another by 90°.

3. The angular transmitter according to claim 1, wherein the at least two sensor elements (6,7) are rotated relative to one another by 60°.

4. The angular transmitter according to claim 1, wherein the at least two sensor elements (6, 7; 6b, 7b, 10) cross one another.

5. The angular transmitter according to claim 1, wherein the at least one sensor (3,3b) is a vertical Hall sensor.

6. The angular transmitter according to claim 1, wherein the at least one sensor (3,3b) is a magneto-resistive sensor.

7. The angular transmitter according to claim 1, wherein the at least one magnetic part (2) is a ring penetrated by a motor shaft (1) of the small electric motor.

8. The angular transmitter according to claim 1, wherein the at least one magnetic part (2c) is a disc attached with one end face on an end of a motor shaft (1) of the small electric motor.

9. The angular transmitter according to claim 1, wherein the at least one magnetic part (2a) is a motor magnet fixedly attached on a motor shaft (1) of the small electric motor.

10. The angular transmitter according to claim 1, further comprising an evaluation unit, wherein output signals (8, 9) of the at least one sensor (3, 3b) are supplied to the evaluation unit.

11. The angular transmitter according to claim 10, wherein the output signals (8, 9) are sine-shaped signals.

12. The angular transmitter according to claim 10, wherein the output signals (8, 9) are phase-shifted by 90°.

13. The angular transmitter according to claim 10, wherein the output signals (8, 9) are phase-shifted by 120°.

14. The angular transmitter according to claim 10, wherein the evaluation unit is a microprocessor.

15. The angular transmitter according to claim 10, wherein the evaluation unit is a digital logic circuit.

16. The angular transmitter according to claim 10, wherein the evaluation unit is an interpolator circuit.

17. The angular transmitter according to claim 10, wherein the output signal (8, 9) provides an absolute position within an integer part of a revolution of the motor shaft (1).

18. The angular transmitter according to claim 10, wherein the output signal (8, 9) provides an absolute position within a revolution of the motor shaft (1).

19. The angular transmitter according to claim 10, wherein the evaluation unit is configured to be arranged within the small electric motor.

20. The angular transmitter according to claim 10, wherein the evaluation unit is configured to be arranged external to the small electric motor.

21. The angular transmitter according to claim 1, wherein the small motor is a brushless direct-current motor with air-core coil.

22. The angular transmitter according to claim 1, wherein the small motor is a direct-current motor with brush and air-core coil.
